(19) United States
(12) Patent Application Publication
(10) Pub. No.: US 2025/0389025 A1
(43) Pub. Date: Dec. 25, 2025

(54) METHOD OF FORMING A LAYER BY ALD

(71) Applicant: ASM IP Holding B.V., Almere (NL)

(72) Inventors: Quentin Nikitas Nicolas Lionel Eric Tricas, Schaerbeek (BE); Werner Knaepen, Leuven (BE); Alessandro Viva, Leuven (BE); Dieter Pierreux, Pepingen (BE)

(21) Appl. No.: 19/244,522

(22) Filed: Jun. 20, 2025

Related U.S. Application Data
(60) Provisional application No. 63/662,228, filed on Jun. 20, 2024.

(51) Int. Cl. C23C 16/52; C23C 16/44; C23C 16/455; H01L 21/02

(52) U.S. Cl. CPC C23C 16/52; C23C 16/4408; C23C 16/45544; H01L 21/0228

(57) ABSTRACT

A method of forming an oxide layer on a plurality of substrates by atomic layer deposition is disclosed. The method comprises providing the plurality of substrates in a process chamber, the plurality of substrates being supported by a substrate boat; and performing a plurality of deposition cycles, each deposition cycle comprising providing a first precursor gas to the process chamber, the first precursor gas comprising a component capable of forming an oxide; providing a purge gas to the process chamber; and providing a second precursor gas to the process chamber, the second precursor gas comprising ozone, the concentration of ozone in the second precursor gas when provided to the process chamber being less than 250 g/m3. The temperature of the process chamber during provision of the second precursor gas is between 50° C. and 500° C. and the process chamber pressure during provision of the second precursor gas is between 500 mTorr and 5 Torr.

### CROSS-REFERENCE TO RELATED APPLICATION(S)

This application claims the benefit of U.S. Provisional Application 63/662,228 filed on Jun. 20, 2024, the entire contents of which are incorporated herein by reference.

### FIELD OF INVENTION

The present disclosure relates to semiconductor processing. More specifically, it relates to a method of forming a layer on a plurality of substrates by atomic layer deposition (ALD) and to a substrate processing system comprising an ALD apparatus for forming the layer.

### BACKGROUND OF THE DISCLOSURE

Material deposition for forming layers on substrates continue to be among the important process steps in the manufacturing of semiconductor devices. Atomic layer deposition, in particular, provides the advantage forming conformal layers that may also allow for controlled tuning of the layer thickness.

One of the challenges associated with ALD may relate to growth per cycle (GPC) as this may also have an influence on the throughput of the deposition process. This may have a negative impact on the cycle time as well as on the operational cost for manufacturing.

Furthermore, with the use of apparatus tailored for batch processing, whereby a plurality of substrates can be processed at a time, a forthcoming challenge associated with ALD may relate to thickness uniformity. Lack of thickness uniformity in a deposition process may pose further challenges that may be associated with subsequent processing that needs to take place in semiconductor manufacturing.

There may, therefore, be a need for improving the ALD process.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

It may be an object of the present disclosure to improve the ALD process. More specifically, it may be an object to provide optimized growth rate per cycle and optimized throughput, improved thickness uniformity and improved electrical properties of layers formed by ALD. It may further be an object to provide layers formed by ALD having reduced contamination levels. To at least partially achieve these objects, the present disclosure may provide a method for forming a layer on a plurality of substrates by ALD and a substrate processing system comprising an ALD apparatus for forming the layer as defined in independent claims. Further embodiments are provided in the dependent claims.

In a first aspect, the present disclosure relates to a method of forming a layer of a material on a plurality of substrates by atomic layer deposition (ALD).

It may be an advantage of embodiments of the first aspect that within wafer non-uniformity (WIWNU) of the plurality of substrates may be reduced. This may allow for improving uniform thickness of the layer across the surface of the substrate on which the layer deposition is carried out. This may advantageously help to improve the yield for the subsequent processes in the semiconductor manufacturing such as for example, further layer depositions, lithography and etch. This may allow for improving throughput of the ALD process by allowing a highly uniform layer to be formed on a plurality of substrates in the same process.

It may be an advantage of embodiments of the first aspect that an increased growth rate of the layer may be obtained. Increased growth rate may further allow for improving the throughput the deposition process.

It may further be an advantage of embodiments of the first aspect that reliability of the semiconductor devices made comprising the layer formed by the ALD process may be improved thanks to the improved thickness uniformity.

It may also be an advantage of embodiments of the first aspect that contamination level in the layer may be reduced. This may advantageously relate to a reduction in, such as for example, carbon contamination or hydrogen contamination.

It may further be an advantage of embodiments of the first aspect that electrical properties of the semiconductor devices made comprising the layer formed by the ALD process may be improved thanks to the reduced contamination.

In a second aspect, the present disclosure relates to a substrate processing system. The substrate processing system may comprise an atomic layer deposition (ALD) apparatus. The ALD apparatus may comprise a controller that may be configured to execute instructions stored in a non-transitory computer readable medium and to cause the ALD apparatus to form the layer of the material on the plurality of substrates in accordance with a method according to embodiments of the first aspect of the present disclosure.

The substrate processing system according to embodiments of the second aspect of the present disclosure may allow for an increased throughput for the deposition process. This may help to decrease cycle time of the deposition process. In semiconductor industry, this may reflect as a decrease in the cycle time of chip production.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure

Like reference numbers will be used for like elements in the drawings unless stated otherwise. Reference signs in the claims shall not be understood as limiting the scope.

FIG. 1 is a schematic view of a substrate processing system according to embodiments of the present invention;

FIG. 2a is a flowchart of an exemplary method according to embodiments of the present invention;

FIG. 2b is a flowchart of an exemplary method according embodiments of the present invention.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

It is to be noticed that the term “comprising”, as used herein, should not be interpreted as being restricted to the means listed thereafter. It does not exclude other elements or steps. It is thus, to be interpreted as specifying the presence of the stated features, steps or components as referred to. However, it does not prevent one or more other steps, components, or features, or groups thereof from being present or being added.

Reference throughout the specification to “embodiments” in various places are not necessarily all referring to the same embodiment, but may. Furthermore, the particular features, structures or characteristics maybe combined in any suitable manner, as would be apparent to one of the ordinary skill in the art from the disclosure, in one or more embodiments.

Reference throughout the specification to “some embodiments” means that a particular structure, feature step described in connection with these embodiments is included in some of the embodiments of the present invention. Thus, phrases appearing such as “in some embodiments” in different places throughout the specification are not necessarily referring to the same collection of embodiments, but may.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may.

It is to be noticed that the term “comprise substantially” used in the claims refers that further components than those specifically mentioned can, but not necessarily have to, be present, namely those not materially affecting the essential characteristics of the material, compound, or composition referred to.

The terms first, second, third, and the like in the description and in the claims, are used for distinguishing between similar elements. They are not necessarily used for describing a sequence, either temporally, spatially, in ranking, or in any other manner. It is to be understood that the terms so used are interchangeable under appropriate circumstances and that the embodiments of the disclosure described herein are capable of operation in other sequences than described or illustrated herein.

The following terms are provided only to help in the understanding of the disclosure.

As used herein and unless provided otherwise, the term “reducing WIWNU” may refer to the reduction in the variation of the thickness of the layer across the surface of the substrate such as for example, from center to edge of the substrate.

The disclosure will now be described by a detailed description of several embodiments of the disclosure. It is clear that other embodiments of the disclosure can be configured according to the knowledge of persons skilled in the art in the absence of departure from the technical teaching of the disclosure. The disclosure is limited only by the terms of the claims included herein.

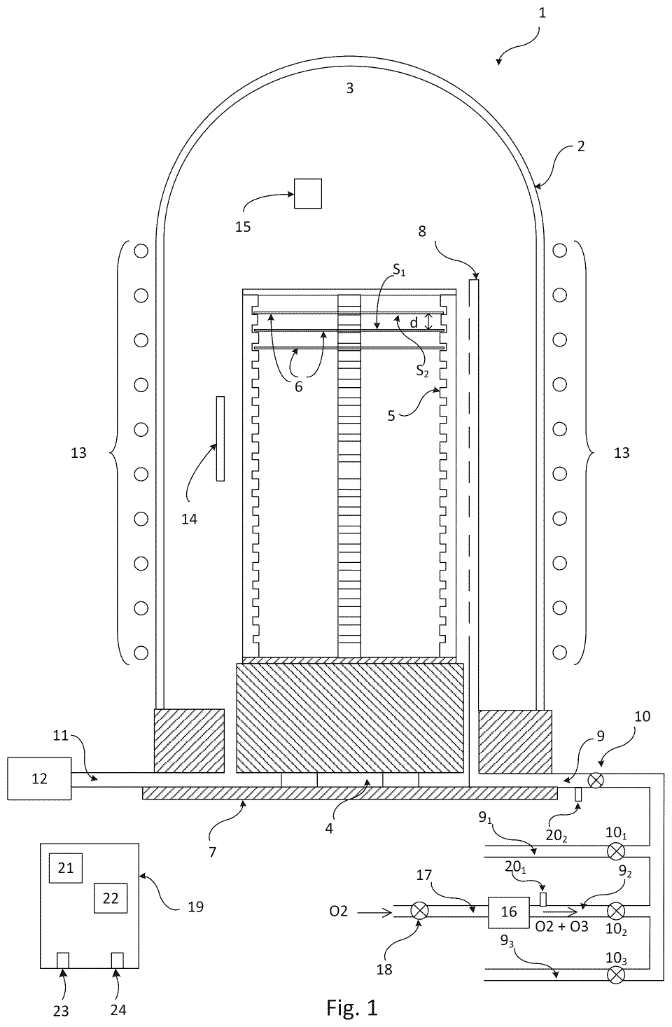

Referring to FIG. 1, an apparatus 1 for processing a plurality of substrates is shown, in which a method according to embodiments of the first aspect of the present disclosure may be carried out. The apparatus 1 comprises a process chamber 2 which is generally bell jar shaped and extends in a longitudinal direction, which may be aligned horizontally or vertically. The process chamber 2 has an open end 3 and a closed end 4. The apparatus 1 comprises a substrate carrier 5 for supporting a plurality of substrates 6 in the process chamber 2. The substrate carrier 5 may be inserted into the process chamber 2 through the open end 3. The open end 3 may be closed off by a door 7.

The plurality of substrates 6 may have a headspace height d. The plurality of substrates 6 may each have a top facing surface S₁, being a surface which is facing towards the closed end 4 of the process chamber 2, and a bottom facing surface S₂, being a surface which is facing towards the open end 3 of the chamber (which may be closed by the door 7). The headspace height d is the distance between a top surface of a substrate S₁ and a surface which is directly facing the top surface of the substrate S₁. The surface directly facing the top surface S₁ of a substrate may be a bottom face S₂ of an adjacent surface. The headspace height d may then be the distance between the top facing surface S₁ of a substrate 6₁ and the bottom facing surface S₂ of an adjacent substrate 6₂, wherein the bottom facing surface S₂ of the adjacent substrate 6₂ is facing the top facing surface S₁. The plurality of substrates 6 may include one or more dummy substrates. The one or more dummy substrates may be provided so as to provide a consistent headspace height d if a number of substrates to be processed is insufficient to provide a consistent headspace height d. Thus the above described headspace height d may be the distance between a top facing surface of a substrate to be processed and a bottom facing surface of an adjacent dummy substrate. The substrate carrier 5 may comprise one or more spacer plates P removably attached to the substrate carrier 5 so as to provide a consistent headspace height d if a number of substrates to be processed is insufficient to provide a consistent headspace height d. Thus the above described headspace height d may be the distance between a top facing surface S₁ of a substrate to be processed and a bottom facing surface of an adjacent spacer plate P.

The apparatus 1 may comprise one or more gas injectors 8 for providing one or more gases to the interior of the process chamber 2. The one or more gas injectors 8 may be dump injectors, multi hole injectors, or other injector types. The one or more gas injectors 8 may be connected one or more gas lines 9 for supplying gas to the one or more injectors 8. The one or more gas lines 9 may include a first gas line 9₁ for providing a first precursor gas, a second gas line 9₂ for providing a second precursor gas, and a third gas line 9₃ for providing a purge gas. One or more flow controllers 10 may be provided in the gas lines 9 so as to control flow rate of gas into the process chamber 2 and consequently the pressure in the process chamber 2. The flow controllers 10 may comprise, for example, one or more of a valve, a mass flow controller, a pressure control valve. For example, flow controllers 10₁, 10₂, 10₃, in gas lines 9₁, 9₂, 9₃ respectively, may be valves which may be in an open or a closed position and flow controller 10 in gas line 9 may comprise a mass flow controller or a pressure control valve. The apparatus 1 may comprise one or more gas exhaust lines 11 for removing gases from the interior of the process chamber 2. The gas exhaust line may be connected to a vacuum pump 12. The apparatus 1 may comprise heating elements 13 for heating the process chamber 2. The apparatus 1 may comprise one or more temperature sensors 14, for example thermocouples, in the process chamber 2 for measuring a temperature in the process chamber 2. The apparatus 1 may comprise one or more pressure sensors 15 in the process chamber 2 for measuring a process chamber pressure.

The apparatus may comprise an ozone generator 16 for receiving oxygen gas (O2) as input from an O2 supply line 17 and providing a mixture of oxygen and ozone (O3) gases as output to a gas line 9, for example via a second gas line 9₂, and thereafter to the process chamber 2. The O2 supply line may comprise a valve or mass flow controller 18. The concentration of ozone in the output from the ozone generator 16 may be controlled by controlling the power to the ozone generator 16 and/or the amount of O2 flow into the ozone generator 16, for example by controlling the valve or mass flow controller 18.

The apparatus 1 may comprise a controller 19 for controlling, for example, the heating elements 13 (thereby controlling the temperature in the process chamber 2), the valves/mass flow controllers 10 (thereby controlling the type of gas provided to the process chamber 2 and the pressure thereof), the power to the ozone generator 14 and/or the valve 16 (thereby controlling the concentration of ozone in the gas output of the ozone generator 14).

The apparatus 1 may comprise one or more ozone sensors 20₁, 20₂, configured to measure ozone concentration in a gas. The one or more ozone sensors may be disposed in a gas line 9, 9₂ for transporting the second precursor gas to the process chamber 2. The ozone sensors may be, for example, ultraviolet spectroscopy based sensors or electrochemical sensors. A first ozone sensor 20₁ may be provided at the output of the ozone generator 16 in the second gas line 9₂. A second ozone sensor 20₂ may be provided in gas line 9 close to the process chamber 2. It may be expected that the concentration measurements for the first and second ozone sensors are substantially the same when gas lines 9 are not heated. Thus, first ozone sensor 20₁ may be considered to be measuring the ozone concentration of the second precursor gas when the second precursor gas is provided to the process chamber 2. In some embodiments, only one ozone sensor may be provided, which may be either the first ozone sensor 20₁ or the second ozone sensor 20₂.

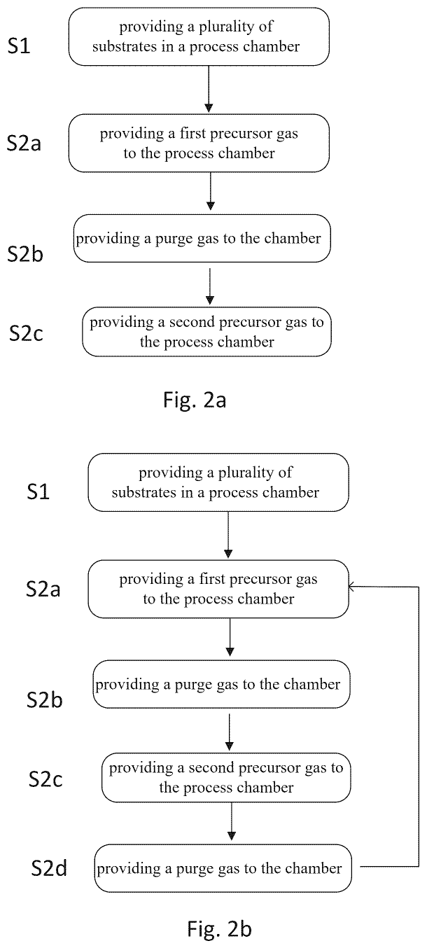

FIG. 2a shows a flowchart of an exemplary method of forming an oxide layer by ALD according to embodiments of the first aspect of the present disclosure.

The method comprises the steps of providing a plurality of substrates in a process chamber, the plurality of substrates being supported by a substrate carrier (step S1); performing a plurality of deposition cycles, each deposition cycle comprising providing a first precursor gas to the process chamber, the first precursor gas comprising a component capable of forming an oxide (step S2a), providing a purge gas to the chamber (S2b), and providing a second precursor gas to the process chamber, the second precursor gas comprising ozone (step S2c). The temperature of the process chamber during provision of the second precursor gas is between 50 C and 500 C, and the pressure in the process chamber during provision of the second precursor gas is between 500 mTorr and 5 Torr. In some embodiments, the temperature of the process chamber during provision of the second precursor gas is between 50 C and 300 C, and the pressure in the process chamber during provision of the second precursor gas is between 500 mTorr and 2 Torr.

Providing the first precursor gas to the process chamber may result in a first monolayer being formed on the plurality of substrates by chemisorption. After purging the process chamber in step S2, provision of the second precursor gas to the process chamber may result in a second monolayer being formed on top of the first layer by chemisorption. The process can be repeated to deposit further monolayers until the formed layer has the required thickness.

Since the first precursor gas comprises a component capable of forming an oxide, and the second precursor gas comprises ozone, the method may result in formation of an oxide layer on the plurality of substrates. The oxide layer may comprise the component capable of forming an oxide, which was previously comprised in the first precursor gas. The component capable of forming an oxide may be a component capable of forming an oxide layer which is in solid form at room temperature.

The second precursor gas comprises ozone, which may decompose upon collision with other gas molecules and/or with surfaces such as an inner wall of the process chamber, a substrate carrier, and the substrates themselves. Once decomposed, component parts may not undergo chemisorption to form a second monolayer over the first monolayer deposited by the first precursor gas on the plurality of substrates, thus limiting growth rate of a layer formed on the plurality of substrates. The average lifetime of the ozone molecules before decomposition may depend on, among others, the temperature of the gas comprising ozone, the partial pressure of ozone in the gas comprising ozone, the concentration of ozone in the gas comprising ozone, the space available above a substrate on which the oxide layer is formed. Embodiments of the present invention may be directed to controlling, directly or indirectly, one or more factors which may influence the average lifetime of the ozone molecules before decomposition, which may help to provide an oxide film having an improved within wafer nonuniformity, i.e. a more uniform film.

The first precursor gas may comprise trimethylaluminum (TMA). TMA itself may not be capable of forming an oxide but TMA comprises aluminum which is capable of forming an oxide. Thus the layer formed on the plurality of substrates may comprise aluminum oxide. The first precursor gas may comprise Bis(diethylamino)silane (BDEAS), which comprises silicon which is capable of forming an oxide. Thus the layer formed on the plurality of substrates may comprise silicon oxide. The first precursor gas may comprise tetrakis(ethylmethlyamino)hafnium, which comprises hafnium which is capable of forming an oxide. Thus the layer formed on the plurality of substrates may comprise hafnium oxide. The first precursor gas may comprise tetrakis(dimethylamino)titanium, which comprises titanium which is capable of forming an oxide. Thus the layer formed on the plurality of substrates may comprise titanium oxide.

The first precursor gas may be provided in the presence of a carrier gas. In embodiments, the carrier gas may comprise N₂, and noble gases such as for example, Ar, Ne, He, Xe and Kr.

In some embodiments, the carrier gas may comprise substantially N₂, Ar, He, Ne, Xe, Kr or combinations thereof.

Providing a purge gas, also referred to herein as a purge gas pulse, to the chamber may comprise providing an inert gas to the process chamber. In some embodiments, the purge gas may be provided to the chamber after step S2c, in addition to the provision in step S2b (FIG. 1b). The purge gas may comprise, for example, N₂, Ar.

In some embodiments, the two instances of providing purge gas may be performed in substantially the same manner, such as for example, providing the same inert gas, with the same flow rate, at the same process chamber temperature and at the same process chamber pressure.

In some embodiments, the instances of providing purge gas may be performed different from one another. The duration of each of the purge gas pulses may, for example, be different from one another depending on which precursor gas needs to be purged. In that respect, a purge gas pulse carried out after the provision of the second precursor may be longer than the duration of provision of the second precursor gas.

The temperature of the process chamber during provision of the second precursor gas is between 50 C and 500 C.

A process chamber temperature towards the lower end of the range may be preferred, for example, in embodiments wherein the plurality of substrates comprise elements which may be damaged by processing at higher temperatures, for example temperatures which may cause effects such as unwanted crystallization of amorphous layers, mobility of doping elements, unwanted oxidation, etc. However, the temperature should be chosen to be high enough that the ALD reaction can occur.

A process chamber temperature towards the higher end of the range may be preferred, for example, in embodiments wherein improved electrical characteristics of the oxide layer are required. A process chamber temperature towards the higher end of the range may be preferred in order to increase growth per cycle. The process chamber temperature may be chosen depending on characteristics of the first or the second precursor gas. For example, the first and/or the second precursor gas may begin to decompose at temperatures above a certain value, or one of the precursors may react with itself and cause chemical vapor deposition to be promoted over ALD.

The process chamber temperature may be chosen to be a value at which the thin film grown on the substrate has desired properties, for example etch resistance.

In embodiments, the process chamber temperature during provision of the second precursor gas may be set to a temperature value in a range of from at least 100 C to at most 300 C, or from at least 120 C to at most 280 C, or from at least 150 C to at most 250 C, or from at least 150 C to at most 200 C, or from at least 200 C to at most 250 C. In embodiments, the process chamber temperature during provision of the second precursor gas may be set to a temperature value in a range of from at least 100 C to at most 500 C, at least 200 C to at most 400 C, at least 300 C to at most 400 C, at least 400 C to at most 500 C.

The process chamber temperature during provision of the first precursor gas may be the same or different to the process chamber temperature during provision of the second precursor gas. The process chamber temperature during provision of the purge gas may be the same or different to the process chamber temperature during provision of the second precursor gas. Thus, the process chamber temperature may be the same throughout performance of steps S2a, S2b, and S2c.

The pressure in the process chamber during provision of the second precursor gas may be between 500 mTorr and 5 Torr, preferably between 500 mTorr and 2 Torr.

In embodiments, the pressure in the process chamber during provision of the second precursor gas may be set to a pressure value in a range of from at least 500 mTorr to at most 1 Torr, or from at least 1 Torr to at most 2 Torr, or from at least 1 Torr to at most 3 Torr, or from at least 2 Torr to at most 3 Torr, or from at least 3 Torr to at most 4 Torr, or from at least 4 Torr to at most 5 Torr, or from at least 700 mTorr to at most 1.5 Torr, or from at least 1 Torr to at most 1.5 Torr, or from at least 1.5 Torr to at most 2 Torr.

In some embodiments, the process chamber pressure during provision of the second precursor gas may be between 1 Torr and 2 Torr and the temperature of the process chamber during provision of the second precursor gas may be between 150 C and 250 C.

The pressure in the process chamber during provision of the second precursor gas may be chosen depending on the chosen process chamber temperature during provision of the second precursor gas. For example, the process chamber temperature during provision of the second precursor gas may be chosen depending on the composition of the substrates, properties of the precursor gases, thermal budget, desired growth per cycle, desired layer properties, or other factors, and the pressure in the process chamber during provision of the second precursor gas may be chosen depending on the chosen temperature.

For example, the process chamber temperature during provision of the second precursor gas may be chosen to be within the range of 150 C to 250 C and the pressure in the process chamber during provision of the second precursor gas may be chosen to be within the range of 1 Torr to 2 Torr, or between 1.2 Torr to 1.8 Torr. The process chamber temperature during provision of the second precursor gas may be chosen to be within the range of 50 C to 150 C and the pressure in the process chamber during provision of the second precursor gas may be chosen to be within the range of 500 mTorr to 1.2 Torr.

The pressure in the process chamber during provision of the second precursor gas may be chosen depending on the chosen temperature of the process chamber temperature during provision of the second precursor gas by considering properties of the second precursor gas at the chosen temperature for a range of pressure values. For example, once the temperature is chosen, the ozone lifetime may be evaluated at that chosen temperature for a series of pressure values, for example by performing experiments using an apparatus as described hereinbefore with reference to FIG. 1. The pressure in the process chamber during provision of the second precursor gas may then be chosen so as to maximise the ozone lifetime at the chosen temperature. Without wishing to be bound by theory, it is thought that by choosing process parameters, such as temperature, pressure, ozone concentration, duration of gas provision, or others, and/or system parameters, such as spacing between substrates, headspace height above a substrate surface on which the oxide layer is to be formed, or others, in order to improve or optimize the ozone lifetime, differences in growth per cycle between the edge and center of the substrate may be reduced and a more uniform film thickness may be obtained.

Providing the substrates 6 to the processing chamber 2 may comprise providing the substrates 6 to the processing chamber 2 in the substrate carrier 5 with a headspace height d. The headspace height d may be less than 20 mm, or less than 15 mm, or less than 10 mm, or less than 5 mm. The headspace height d may be between 2 mm and 20 mm, between 2 mm and 15 mm, between 2 mm and 10 mm, between 2 mm and 8 mm.

Providing the substrates 6 to the processing chamber 2 may comprise providing at least 100 substrates 6 to the processing chamber 2 in the substrate carrier 5. In some embodiments, at least 120, at least 140, or at least 160 substrates 6 may be provided to the processing chamber 2 in the substrate carrier 5. Providing at least 100 substrates in a method according to embodiments of the present invention allows for high throughput to be achieved while maintaining an improved WIWNU.

In some embodiments, the headspace height may be determined by the number of substrates 6 required to be provided to the processing chamber in order to achieve a certain throughput. The ozone partial pressure in the second precursor gas in the process chamber during provision of the second precursor gas may be chosen depending on the headspace height, for example a lower headspace height may requires a higher value of ozone partial pressure.

In some embodiments, the first precursor gas may be provided to the process chamber with a pressure value that is the same as the pressure in the process chamber during provision of the second precursor gas. In some embodiments, the first precursor gas may be provided to the process chamber with a process chamber pressure value that is different to the process chamber pressure during provision of the second precursor gas. In some embodiments, the pressure in the process chamber during provision of the first precursor gas may be substantially the same as the pressure in the process chamber during provision of the second precursor gas and the process chamber pressure during provision of the purge gas to the process chamber may be different to the process chamber pressure during provision of the first precursor gas and the process chamber pressure during provision of the second precursor gas. In some embodiments, the process chamber pressure during provision of the first precursor gas may be different to the process chamber pressure during provision of the second precursor gas, and the process chamber pressure during provision of the purge gas to the process chamber may be less than both the process chamber pressure during provision of the first precursor gas and the process chamber pressure during provision of the second precursor gas. In some embodiments, the process chamber pressure during provision of the first precursor gas, the process chamber pressure during provision of the second precursor gas, and the process chamber pressure during provision of the purge gas to the process chamber may be substantially equal.

In some embodiments, the purge gas may be provided to the process chamber with a flow rate of at least 10 standard liter per minute (slm). In some embodiments, the purge gas may be provided to the process chamber with a flow rate of at least 20 standard liter per minute (slm). Providing the purge gas to the process chamber with a relatively large flow rate, for example greater than 10 slm, may allow for increased species desorption at substrate edges, which may help to decrease the growth per cycle at the edge of a substrate to be more in line with the GPC at the centre of a substrate, while limiting the throughput loss.

The purge gas may be provided to the process chamber 2 via a purge gas injector 8. The purge gas injector 8 may be a multi-hole injector. Providing the purge gas using a multi hole injector may allow more uniform purging throughout the process chamber 2, as compared with an open-end dump injector configured to provide gas through one outlet hole only, which may cause over purging of substrates closer to the closed end of the process chamber 2.

The second precursor gas may comprise a mixture of ozone and another gas. For example, the second precursor gas may comprise a mixture of ozone and oxygen. The second precursor gas may comprise a mixture of ozone, oxygen, and nitrogen.

The concentration of ozone in the second precursor gas may be chosen so as to increase ozone lifetime between the substrates. For example, the second precursor gas may have an ozone concentration of less than 250 g/m³ when provided to the process chamber 2. The second precursor gas may have an ozone concentration of less than 200 g/m³ when provided to the process chamber 2. Such concentration values may allow for limitation of the gradient of O3 partial pressure in the headspace above substrates, which may provide increased ozone lifetime and improved WiWNU.

In embodiments, the first precursor gas may be a metal organic precursor.

In some embodiments, the first precursor gas may comprise a transition metal. In some embodiments, the first precursor gas may comprise a vapor of a transition metal chloride. The vapor of the transition metal chloride may be provided to the process chamber with the help of a carrier gas. In some embodiments, the first precursor gas may comprise substantially the vapor of the transition metal chloride.

In some embodiments, the first precursor gas may comprise a vapor of HfCl₄, TaCl₅, TiCl₄, MoCl₅, ZrCl₄, MoO₂Cl₂, VCl₄.

In some embodiments, the first precursor gas may comprise a Group III element or a Group IV element.

In embodiments, the first precursor gas may comprise Al(CH₃)₃ or AlCl₃. In embodiments, the first precursor gas may comprise a Si-containing gas. In embodiments, the Si-containing gas may be metal organic silicon precursor. In embodiments, the Si-containing gas may be a silicon halide. This may lead to the formation of a silicon-comprising layer by ALD. The silicon halide may be represented by the formula SiₙX₂ₙ₊₂, where X is halogen and where n is an integer from at least 1 to 5.

In some embodiments, the first precursor gas may comprise octa-chloro-tri-silane, hexa-chloro-di-silane or silicon tetrachloride. In other words, the silicon halide may be octa-chloro-tri-silane, hexa-chloro-di-silane or silicon tetrachloride.

In embodiments, the method may further comprise performing a thermal treatment process after performing the plurality of deposition cycles. The thermal treatment process may be at least one of an in-situ and an ex-situ thermal treatment process. Depending the ambient, the temperature, the pressure of the thermal treatment process, it may advantageously allow for reducing contamination in the layer.

The thermal treatment process may be performed under an ambient that may comprise at least one of O₃, O₂, H₂O and N₂. This thermal treatment process may help in reducing contamination in the ALD layer, such as for example, carbon contamination or hydrogen contamination.

In some embodiments, the thermal treatment process may be performed after forming the desired ALD layer thickness. Thus, the method may further comprise performing the thermal treatment after performing the plurality of deposition cycles aiding to get the desired thickness. In other words, the thermal treatment process may be performed after upon completion of the formation of the ALD layer with the desired thickness.

In some embodiments, the method may further comprise repeating the performing of the plurality of deposition cycles and the performing of the at least one of an in-situ and an ex-situ thermal treatment process. This may be advantageous in completing the formation of the desired ALD layer not only incrementally but also helping to subsequently remove the contamination in each incremental layer.

In embodiments, the thermal treatment process may be an in-situ thermal treatment process, an ex-situ thermal treatment process or a combination of both.

Thus, in some embodiments, the thermal treatment process may be performed in-situ at a temperature in a range of 450° C. to 1000° C. The process chamber pressure in these embodiments may be in a range of 0.1 Torr to 10 Torr for a duration of in a range of 15 minutes to 5 hours. The in-situ thermal treatment process may be performed under an ambient comprising O₃, O₂, H₂O and N₂.

The temperature may, in embodiments be from at least 450° C. to at most 550° C. or from at least 550° C. to at most 650° C. or from at least 650° C. to at most 750° C. or from at least 750° C. to at most 850° C. or from at least 850° C. to at most 1000° C.

In some embodiments, the thermal treatment process may be performed ex-situ at a temperature of about 1000° C. This ex-situ thermal treatment may be performed for a duration in a range of 1 minute to 5 minutes. The ex-situ thermal treatment process may be performed under an ambient comprising N₂ and O₂.

Referring once more to FIG. 1, the substrate processing apparatus 1 comprises a controller 19 which is configured to perform a method according to embodiments of the present invention as described herein. The controller 19 may be implemented in hardware or in software. The controller 19 may be (physically) part of a central control module (not shown) or may be (physically) separate from and in communication with a central control module (not shown). The controller 19 may comprise a memory 21 configured to store instructions for performing a method according to embodiments of the present invention. The controller 19 may comprise a processor 22 which may be configured for processing and carrying out instructions loaded from the memory 20. The controller 19 may comprise one or more inputs 23 for receiving data, signals, and/or instructions from elements comprised in the substrate processing apparatus 1, for example measurements of pressure, temperature, ozone concentration, etc from pressure sensors, temperature sensors, ozone concentration sensors, etc. The controller 19 may comprise one or more outputs 24 for providing data, signals, and/or instructions to elements comprised in the substrate processing apparatus 1, for example ozone generator 16, flow controllers 10, heaters 13, in order to control, for example, ozone concentration in the second precursor gas, process chamber pressure, and process chamber temperature, respectively.

The embodiments of the present disclosure do not limit the scope of invention as these embodiments are defined by the claims appended herein and their legal equivalents. Any equivalent embodiments are intended to be within the scope of this invention. Modifications of the disclosure that are different from one another, in addition to those disclosed herein, may become apparent to those skilled in the art. Such modifications and the embodiments originating therefrom, are also intended to fall within the scope of the claims appended herein.

1. A method of forming an oxide layer on a plurality of substrates by atomic layer deposition, the method comprising the steps of:
providing the plurality of substrates in a process chamber, the plurality of substrates being supported by a substrate boat; and
performing a plurality of deposition cycles, each deposition cycle comprising:
providing a first precursor gas to the process chamber, the first precursor gas comprising a component capable of forming an oxide;
providing a purge gas to the process chamber; and
providing a second precursor gas to the process chamber, the second precursor gas comprising ozone, a concentration of ozone in the second precursor gas when provided to the process chamber being less than 250 g/m³,
wherein a temperature of the process chamber during provision of the second precursor gas is between 50° C. and 500° C. and a process chamber pressure during provision of the second precursor gas is between 500 mTorr and 5 Torr.

2. A method according to claim 1, wherein the process chamber pressure during provision of the second precursor gas is between 500 mTorr and 2 Torr and the temperature of the process chamber during provision of the second precursor gas is between 50° C. and 300° C.

3. A method according to claim 1, wherein the temperature of the process chamber during provision of the second precursor gas is between 150° C. and 250° C. and the process chamber pressure during provision of the second precursor gas is between 1 Torr and 2 Torr.

4. A method according to claim 1, wherein the concentration of ozone in the second precursor gas is less than 200 g/m³.

5. A method according to claim 1, wherein the substrates in the substrate boat have a headspace height which is less than 10 mm.

6. A method according to claim 1, wherein the process chamber pressure during provision of the first precursor gas is equal to the process chamber pressure during provision of the second precursor gas.

7. A method according to claim 1, wherein the process chamber pressure during provision of the purge gas is equal to the process chamber pressure during provision of the second precursor gas.

8. A method according to claim 1, wherein the substrates in the substrate boat have a headspace height and wherein the process chamber pressure during provision of the second precursor gas is chosen based on the headspace height.

9. A method according to claim 1, wherein the temperature of the process chamber during provision of the second precursor gas is a predetermined value and the process chamber pressure during provision of the second precursor gas is chosen based on the predetermined value.

10. A method according to claim 1, wherein the purge gas is provided to the process chamber with a flow rate of at least 20 standard liter per minute.

11. A method according to claim 1, wherein the second precursor gas comprises a mixture of oxygen and ozone.

12. A method according to claim 1, wherein the first precursor gas comprises a vapor of a transition metal chloride.

13. A method according to claim 12, wherein the first precursor gas comprises a vapor of HfCl₄, TaCl₅, TiCl₄, MoCl₅, MoO₂Cl₂, VCl₄, or SnCl₄.

14. A method according to claim 1, wherein the first precursor gas comprises Al₂(CH₃)₆ or Al(CH₃)₃ or AlCl₃.

15. A method according to claim 1, wherein the first precursor gas comprises a silicon halide.

16. A method according to claim 15, wherein the first precursor gas comprises octa-chloro-tri-silane, hexa-chloro-di-silane or silicon tetrachloride.

17. A method according to claim 1, wherein the first precursor gas comprises a metal organic precursor.

18. A substrate processing system comprising:
a process chamber configured to receive a substrate carrier supporting a plurality of substrates,
a heater configured for heating and maintaining process temperature in the process chamber,
a pressure controller configured for attaining and maintaining process pressure in the process chamber,
at least one gas injector,
a controller configured to execute instructions stored in a non-transitory computer readable medium and to cause the substrate processing system to form an oxide layer on the plurality of substrates in accordance with a method comprising the steps of:
providing the plurality of substrates in a process chamber, the plurality of substrates being supported by a substrate boat; and
performing a plurality of deposition cycles, each deposition cycle comprising:
providing a first precursor gas to the process chamber, the first precursor gas comprising a component capable of forming an oxide;
providing a purge gas to the process chamber; and
providing a second precursor gas to the process chamber, the second precursor gas comprising ozone, a concentration of ozone in the second precursor gas when provided to the process chamber being less than 250 g/m³,
wherein a temperature of the process chamber during provision of the second precursor gas is between 50° C. and 500° C. and a pressure of the process chamber during provision of the second precursor gas is between 500 mTorr and 5 Torr.

19. The substrate processing system according to claim 18, wherein the substrate processing system is a vertical furnace batch atomic layer deposition apparatus.

20. The substrate processing system according to claim 18, further comprising an ozone generator configured to receive oxygen gas as input and to output a mixture of oxygen and ozone gas, wherein the controller is configured to control the ozone generator so as to achieve a desired concentration of ozone.
